(19) United States
(12) Patent Application Publication
(10) Pub. No.: US 2007/0267730 A1
(43) Pub. Date: Nov. 22, 2007

(54) Wafer level semiconductor chip packages and methods of making the same

(75) Inventors: Victor Liew, Pleasanton, CA (US); Giles Humpston, Aylesbury (GB); Belgacem Haba, Saratoga, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/435,345

(22) Filed: May 16, 2006

(51) Int. Cl. H01L 23/02

(52) U.S. Cl. 257/678

(57) ABSTRACT

A wafer having a front surface and contacts exposed at the front surface is treated by forming electrically conductive risers projecting upwardly from the contacts as, for example, by electroless plating, and then applying a flowable material over the front surface of the device, around the risers, to form a dielectric layer with the risers exposed at a top surface of the dielectric layer facing away from the device. Traces extending over the top surface of the dielectric layer may be formed, and may be connected to at least some of the risers.

### FIELD OF THE INVENTION

The present invention relates to packaging of microelectronic elements.

### BACKGROUND OF THE INVENTION

Semiconductor chips typically are provided as flat, relatively thin bodies formed principally of semiconductor material. The body has front and rear surfaces, and has contacts exposed at the front surface. These contacts are electrically connected to the numerous electronic circuit elements disposed within the body. Chips typically are formed by processing large, flat wafers of semiconductor material to form the various internal electronic circuit elements, and to form the contacts. The wafer processing typically also includes formation of an inert passivation layer such as a layer of an oxide, nitride or polymeric dielectric on those areas of the wafer surface not occupied by the contacts. After processing, the wafer is cut apart to yield the individual chips.

Chips commonly are provided with packages which provide environmental and mechanical protection to the body, and which facilitate connection of the chip contacts to external circuitry as, for example, to a circuit panel. The package may include terminals connected to the contacts. The terminals may be disposed at a greater spacing or pitch than the contacts, so that the packaged chip can be readily mounted to a circuit panel by solder-bonding the terminals to the corresponding contact pads on the circuit panel. In some instances, the terminals may be movable to some extent relative to the body of the chip. Such movement can relieve stresses in the solder bonds between the terminals and the circuit panel due to factors such as differential thermal expansion and contraction of the chip and the circuit panel during the soldering process or during service of the assembly. In some instances, the package may provide signal paths for transmission of signals between contacts on the chip. These signal paths supplement signals paths provided by internal conductors within the body of the chip. This can simplify the design of the chip itself, and can also provide benefits such as faster transmission of signals between widely separated elements of the chip.

Many packages are formed by assembling individual chips to components of the package. However, this requires handling of the individual chips after severance of the wafer. It has been proposed to fabricate chip packages by providing some or all the structures which constitute the package on the front surface of the wafer before severing the wafer to form the individual chips. This approach is commonly referred to as “wafer level” packaging. For example, as shown in Kwan, U.S. Pat. No. 6,407,459, a patterned metal layer can be deposited on the chips to define leads connected to the contacts of the chip and also define terminal pads at locations offset from the contacts, and a dielectric layer can be deposited over the leads. Takiar et al., U.S. Pat. No. 6,521,970, discloses fabrication of lead structures in the form of cantilever beams spaced apart from the chip surface, these lead structures also defining terminals offset from the chip contacts. Lo et al., U.S. Pat. No. 6,914,333, discloses a chip package formed by fabricating a dielectric layer with vertically extensive bumps or projections and with leads extending up these bumps or projections from the contact pads to terminal pads on the tops of the projections. This structure assertedly provides some compliancy in the dielectric bumps.

Wafer level packaging processes heretofore typically have required numerous process steps including selective formation of features. For example, the dielectric layers used in these processes typically must be photographically patterned. The requirement for such patterning limits the choice of materials to only those materials which are photosensitive, such as photoimageable polyimides. Also, typical wafer level packaging processes require formation of holes in the dielectric layer in registry with the contacts of the wafer, followed by deposition and patterning of a metal to form metallic features extending through the holes onto the surface of the dielectric layer and onto any bumps or projections of the dielectric layer. Because the metallic features must extend through an appreciable vertical extent, some difficulties are encountered in the photographic patterning process used to pattern the resist.

Thus, despite considerable effort devoted in the art heretofore to development of wafer level packaging processes and structures, further improvement would be desirable.

### SUMMARY OF THE INVENTION

One aspect of the invention provides methods of treating microelectronic devices such as wafers. A method according to this aspect of the invention desirably includes the step of forming electrically conductive risers projecting upwardly from contacts exposed at a front surface of the device, and then applying a first flowable material over the front surface of the device around the risers so as to form a first dielectric layer. The step of applying the first flowable material desirably is performed so that the risers remain exposed at a top surface of the dielectric layer facing away from the device. The method according to this aspect of the invention desirably further includes forming first electrically conductive traces extending over the top surface of the dielectric layer, at least some of these traces desirably being connected to at least some of the risers and hence to the contacts. The step of forming risers most preferably is performed by using a self-selective deposition technique such as electroless plating. The step of applying the flowable material may be performed non-selectively, as by spin-coating. The flowable material may form menisci connecting the top surface of the flowable material with the risers. These menisci desirably provide smooth transitions between the risers and the remainder of the top surface. The method may also include applying a second flowable material over the top surface of the first dielectric layer and over the first traces, so as to form a second dielectric layer over at least a portion of the first dielectric layer. Here again, at least some of the risers desirably are exposed at the top surface of the second dielectric layer, and further traces may be formed on the second dielectric layer. These traces may cross the first traces without being electrically connected thereto, and hence the structure may provide substantial routing capability.

A further aspect of the invention provides a packaged microelectronic device including a device body with a front surface and contacts exposed at the front surface. The device desirably further includes a first dielectric layer overlying the front surface of the body, the first dielectric layer having a top surface facing away from the body. The device additionally includes electrically conductive risers projecting upwardly from the contacts. The risers desirably have tips remote from the body exposed at the top surface. The top surface most preferably has vertically curved surface regions contiguous with surfaces of the risers. These vertically curved surface regions may be formed in a process as discussed above from the menisci formed during application of a flowable dielectric material.

Yet another aspect of the invention provides further methods of making packaged microelectronic devices. The methods according to this aspect of the invention desirably include forming a dielectric structure on a front surface of the device and forming continuous traces extending on the dielectric structure using a photographic patterning process. The patterning process desirably includes a first exposure to form portions of the traces extending in a first range of vertical positions and a second exposure to form portions of the traces extending in a second range of vertical positions. For example, where the dielectric structure includes a dielectric layer having a top surface, holes extending through the dielectric layer, and projections extending upwardly from the top surface of the dielectric layer, the first exposure may form portions of the traces in the holes, and the second exposure may form portions of the traces on the projections, these portions being continuous with one another.

Yet another aspect of the invention provides a microelectronic device comprising a body having a front face and contacts exposed at the front face, a dielectric structure overlying the front face, and electrically conductive traces extending from the contacts over the dielectric structure, the traces including pads overlying the dielectric structure. The device according to this aspect of the invention desirably includes electrically conductive terminal structures overlying the pads. Each of the terminal structures desirably includes a base and a pin projecting upwardly from the base, away from the device. The bases most preferably have larger diameters than the pins. The bases help to prevent damage to the dielectric structure when vertical loads are applied to the pins as, for example, during testing or engagement of the device with a circuit panel.

### BRIEF DESCRIPTION OF THE DRAWINGS

FIG. 1 is a fragmentary, diagrammatic sectional view depicting a portion of a device during a process according to one embodiment of the invention.

FIG. 2 is a view similar to FIG. 1, but depicting the device at a later stage in the process.

FIGS. 3 and 4 are diagrammatic, fragmentary sectional views on an enlarged scale depicting the areas indicated at 3 and 4 in FIG. 2.

FIG. 5 is a view similar to FIGS. 1 and 2, but depicting the device at a still later stage of the process.

FIG. 6 is a fragmentary top plan view of the device formed in the process of FIGS. 1-5.

FIG. 7 is a fragmentary sectional view depicting a device according to a further embodiment of the invention.

FIG. 8 is a fragmentary top plan view depicting a portion of the device shown in FIG. 7.

FIG. 9 is a fragmentary sectional view depicting a portion of a device according to yet another embodiment of the invention.

FIG. 10 is a fragmentary, diagrammatic sectional view depicting a device according to a still further embodiment of the invention.

FIG. 11 is a fragmentary sectional view depicting a portion of a device according to a further embodiment of the invention.

FIG. 12 is a fragmentary top plan view of the device shown in FIG. 11.

FIG. 13 is a diagrammatic, fragmentary sectional view depicting a portion of a device during a process according to yet another embodiment of the invention.

FIG. 14 is a view similar to FIG. 13, depicting the device of FIG. 13 during a later stage of the process.

FIG. 15 is a view similar to FIG. 14, but depicting a device according to a further embodiment of the invention.

### DETAILED DESCRIPTION

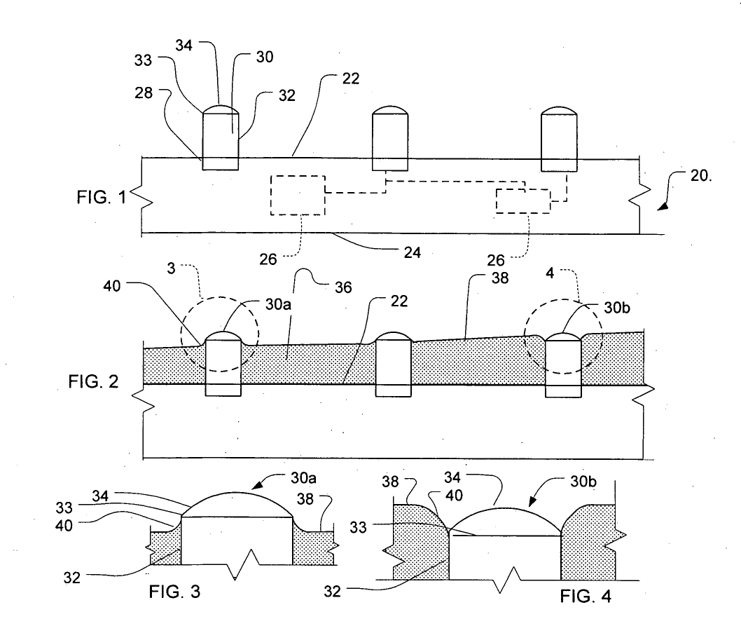

A process in accordance with one embodiment of the present invention treats a microelectronic device which, in this case, is a wafer 20 (FIG. 1). Wafer 20 is a conventional unitary body having a generally planar front surface 22 and rear surface 24. Numerous electrical devices 26 such as active semiconductor elements including transistors, diodes, and the like and passive electrical elements such as resistors, capacitors, and inductors, as well as circuits formed from these elements, are formed within the body 20. The front surface 22 of the body is predominantly formed from a dielectric material such as a silicon oxide, silicon nitride, or polymeric dielectric. The body also includes electrically conductive contacts 28 exposed at the front surface 22. As referred to herein, a conductive element such as a contact is “exposed at” a surface if the contact can be accessed by a theoretical point moving toward the surface in the direction perpendicular to the surface. Thus, contacts 28 may be recessed relative to surrounding portions of surface 22, flush with the surface as depicted in FIG. 1, or raised somewhat relative to the surrounding portions of the surface.

In a first step of the process, electrically conductive risers 30 are formed on contacts 28. The risers may be formed from essentially any conductive material, but most desirably are formed from materials which are compatible with the materials of contacts 28 and which do not give rise to any undesirable metallurgical interactions. Thus, risers 30 may be formed from materials of the type commonly used in metallization of semiconductor chip contacts. For example, where contacts 28 are formed from aluminum, risers 30 may be formed by applying a zincate to rid the contacts of oxides, then a thin layer of nickel first, followed by copper or gold. Other combinations of metal such as titanium, platinum, and gold may be employed. Most desirably, the risers are formed by a self-selective deposition process. As referred to herein, a self-selective process is one in which the materials constituting the risers 30 deposit preferentially on the materials of the contacts 28 when both the contacts and the surrounding dielectric material of surface 22 are exposed to the materials under deposition conditions. One such self-selective process is electroless plating. In electroless plating, the surface 22 including contacts 28 is exposed to one or more baths of a liquid which contains a metal or metals to be deposited, and the metals deposit preferentially on the metallic contacts 28 with little or no deposition on the surrounding dielectric of surface 22. Electroless plating per se is a well-known process, and accordingly, need not be further described herein.

The deposition process is continued until the risers 30 have developed to a desired height above the front surface 22 of the wafer. This height should be about equal to the thickness of a dielectric layer to be deposited in a subsequent step or slightly greater than the thickness of such dielectric layer. For example, risers 30 may project above the front surface 22 by about 1 micron to about 100 microns or more. Risers 30 are depicted in FIG. 1 as precisely cylindrical bodies with side walls 32 exactly perpendicular to the front surface 22, and hence, exactly vertical. In practice, risers deposited by electroless plating may have side walls which bulge outwardly or taper inwardly. The risers deposited by electroless plating tend to have domed top surfaces 34, so that the height of the riser is at a maximum near the horizontal center of the riser. The top surface 34 of the riser may be smoothly curved as depicted or may have some degree of roughness, depending upon the precise conditions used for deposition to form the riser. The juncture between the top surface 34 and the side wall 32 is indicated at 33; in practice, this juncture may be a gradual transition rather than a sharp corner.

In those cases where the deposition process used to form the riser deposits a small amount of material on dielectric surface 22, to a thickness substantially less than the height of riser 30, this minor amount of material may be removed by subjecting the entire front surface to a brief etching process sufficient to remove the relatively small thickness deposited on the dielectric. Such an etching process may be performed non-selectively, without masking, inasmuch as only a small amount of material will be removed from the risers during the etching process. Typically, however, this step is not required.

A first dielectric layer 36 (FIG. 2) is applied onto the front surface 22 of the wafer. Most preferably, the first dielectric layer is applied by depositing a flowable material onto front surface 22 and causing the material to flow across the surface without masking, so that the flowable material is distributed onto all portions of the front surface, other than those occupied by the risers 30. One example of such a distribution process is the process commonly known as spin-coating. In spin-coating, a flowable composition is deposited onto the surface of a wafer, and the wafer is spun so that centrifugal force causes the composition to distribute itself over the surface of the wafer and form a more or less uniform thickness. The flowable composition most preferably wets the front surface 22 of the body, and also most desirably wets the side surfaces 32 of the risers 30. The liquid composition need not, and desirably does not, wet the tip surfaces 34 of the risers. The tip surfaces typically will have a different surface texture than the side surfaces. The flowable composition may be essentially any dielectric-forming composition as, for example, an epoxy, silicone, or polyimide composition. The composition, although flowable, desirably has substantial viscosity.

The thickness of layer 36 is controlled by factors such as the amount of material deposited during the spin-coating process. The thickness is selected so that the top surface 38 of layer 36 lies at a height above front surface 22 close to the top ends or tips 34 of the posts 30. As indicated in FIG. 2, the top surface 38 of layer 36 may not be precisely uniform in height. However, the deviation from a precisely horizontal plane, exactly parallel to the front surface 22 of the wafer is greatly exaggerated in FIG. 2 for clarity of illustration. In practice, the deviation from exact horizontal planarity is small in comparison to the thickness of the layer, and accordingly, the top surface 38 in those regions of the top surface remote from risers 30 can be considered as a substantially horizontal surface. The regions of top surface 38 remote from the risers are referred to herein as the principal regions of the top surface. The risers 30 may also differ slightly in height. Deviations from exact uniformity in the thickness of layer 36 and the height of risers 30 may cause the general plane of the top surface 38 to lie slightly above or slightly below the location where the tip surface 34 joins the side wall 32 of the riser.

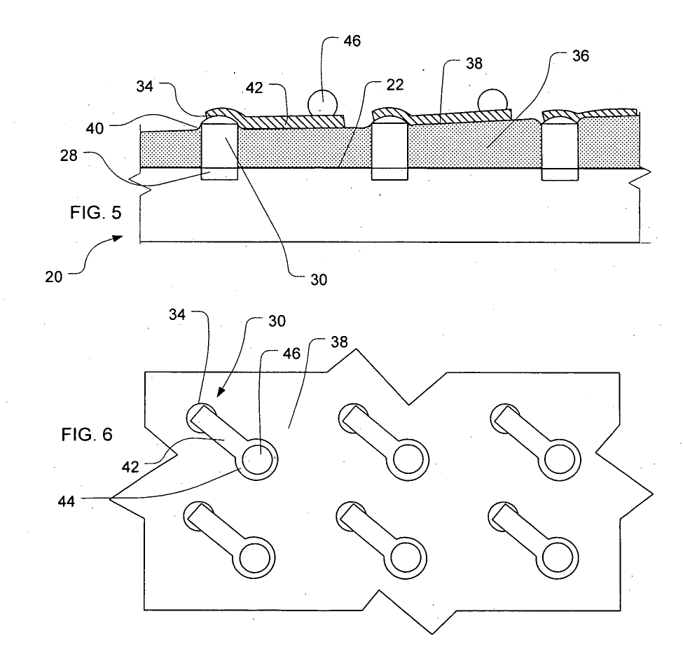

The flowable composition forming layer 36 forms menisci 40 extending between the principal region 38 of the top surface and the surfaces of the riser. For example, as best seen in FIG. 3, the principal generally horizontal top surface 38 of the layer lies below the juncture 33 between the top and side surfaces of riser 30a, and hence the menisci 40 at riser 30a curve upwardly toward the juncture 33. At riser 30b, the generally horizontal principal region of top surface 38 lies above the juncture 33 between the tip surface 34 and side wall 32 of the riser. Thus, the menisci 40 at this riser curve downwardly, as best seen in FIG. 4.

After the flowable composition has been applied to form the layer 36, the layer is cured to a solid condition. The curing process will depend upon the liquid composition and may include, for example, application of radiant energy, heat, or the like, or simple passage of time to allow a chemical reaction to occur at room temperature. The cured layer retains the configuration of the layer discussed above. Thus, the top surface 38 of the cured layer 36 includes the substantially flat, horizontal principal regions and menisci 40. The menisci 40 constitute vertically curved regions of the top surface 38.

After curing the layer, traces 42 are formed on the top surface of the structure. Thus, the traces 42 overlie the tips 34 of the risers 30 and overlie the principal regions of the top surface 38 of layer 36, as well as the vertically curved surface regions 40 formed from the menisci. The vertically curved surface regions provide smooth transitions between the tips of the risers and the principal regions of the top surface. As best seen in FIG. 6, in the particular embodiment shown, each trace 42 has a terminal in the form of a generally circular pad 44 at the end of the trace remote from the associated riser 30. The particular pattern of traces and terminals depicted in FIG. 6 is merely provided for purposes of illustration. It is not essential that every trace, or any of the traces, have a terminal. For example, some or all of the traces 42 can extend between risers 30 so as to provide interconnections between these risers, and thereby interconnect the associated contacts 28 (FIG. 5) of the body. In other cases, a particular trace may be connected to two or more terminals. Also, the traces need not be straight or parallel to one another. The traces can be formed by any process commonly utilized to deposit and form traces on circuit panels. For example, in a conventional thin-film metallization process, a layer of chromium is deposited first by sputtering, followed by sputter-deposition of a layer of copper and, typically, deposition of a layer of gold to provide corrosion resistance. The chromium promotes adhesion between the copper and the dielectric. Conventional patterning techniques may be employed. For example, the metals used to form the traces may be deposited as complete layers overlying the entire top surface of the structure, including the tips 34 of the risers and top surface 38 of dielectric layer 36. After deposition, a photoresist may be applied and patterned by selectively exposing the resist to light, developing the resist and removing unwanted portions of the resist, leaving those areas of the metal layers which are to form the traces and terminals covered by the resist, with the other areas uncovered. After patterning the resist, the structure is exposed to an etchant to remove the metal. Alternatively, a photoresist may be applied and patterned by selective exposure to light so as to leave openings in the areas where the leads and terminals are to be formed, whereupon the metal layers are deposited over the resist and into the openings, and the resist is removed so as to remove the unwanted portions of the metal layers. A conventional solder mask (not shown) may be applied over the traces so as to leave openings in the solder mask only at the terminals. Masses of a conductive bonding material such as solder balls 46 may be applied on the terminals.

Body 20 and dielectric layer 36 may be severed by cutting them along predetermined severance lines (not shown) so as to separate the device into a plurality of individual units, each including one or more chips formed from the wafer body, and the overlying portions of the dielectric layer along with the associated leads, terminals, and bonding material masses. The severing operation may be conducted using conventional wafer severing equipment such as a wafer saw. Also, the severing step may be performed at any point during the process, but preferably is performed at a point after application of risers 30 and layer 36.

The resulting structure has substantially planar traces 42 and the associated terminals 44 separated from the front surface 22 of the wafer by the dielectric layer 36. Although the traces are shown as having some vertical topography in FIG. 5, it should be appreciated that the vertical dimensions of the traces caused by the tips of the risers and the menisci are greatly exaggerated in the drawings for purposes of illustration. In practice, the traces are almost perfectly planar and typically deviate from perfect planarity by about a few microns or less. Thus, the process of deposition and photographic exposure used to form the traces can be performed readily. For example, the process avoids the problems encountered in attempting to deposit thin layers of metal onto the vertically extensive side walls of holes in a dielectric layer. Deposition onto the vertically extensive walls tends to yield structures which are thinner than the horizontally extending portions of the traces. Moreover, the vertically curved surfaces 40 of the dielectric layer top surface at its junctures with the risers provides a smooth transition between the tip surfaces 34 of the risers and the principal region of dielectric layer top surface 38. These factors tend to provide reliable traces. Moreover, because the traces are formed in an essentially planar condition, the photographic exposure process used to pattern the resist is simplified.

The risers 30 may have relatively small horizontal dimensions or diameters; there is no need to provide large holes in a dielectric layer to accommodate subsequent deposition of a metal. Thus, the process can be used even where the contacts 28 are closely spaced as, for example, where the contacts are provided in rows. For example, the leads 42 may spread out from such a row to an array of terminals 42 distributed evenly over the dielectric layer.

Dielectric layer 36 may be essentially as thick as desired. As mentioned above, the risers 30 may be fabricated to a wide range of heights, and the process of fabricating the traces is essentially uninfluenced by the thickness of the dielectric layer. By contrast, processes which deposit thin films of metal into holes in a previously formed dielectric layer so as to provide a vertical conductor associated with the trace become progressively more difficult as the thickness of the dielectric layer increases.

The ability to use a relatively thick dielectric layer means that the dielectric layer can be thick enough to provide substantial compliance. The compliance of the dielectric layer depends upon its composition and its thickness. Typically, the polymeric materials of the dielectric layer have elastic moduli much smaller than the elastic modulus of the body 20. In some cases, the materials of the dielectric layer may include materials such as soft silicone compositions or soft flexibilized epoxies. These provide greater compliance for a given thickness.

The compliance of the dielectric layer can allow movement of the terminals 44 relative to the contacts 28 of the body. During manufacture, the terminals 44 may be engaged with an electrical test fixture such as a probe card, so that the electronic devices within body 20, as well as the electrical integrity of the traces and risers, can be verified. This step may be performed before or after application of the bonding material masses 46. The ability of the terminals 44 to move relative to the body can simplify engagement of the terminals with the electrically conductive elements of the test fixture. The devices formed in the process may be attached to a circuit panel, as by surface-mounting using the bonding material masses 46 to connect the terminals 44 with contact pads of the circuit panel. During the bonding operation and during service, differential thermal expansion and contraction of the circuit panel and the body may occur. The ability of the terminals to move relative to the body tends to reduce stress in the joints between the terminals and the contact pads of the circuit panel thus tends to improve reliability.

In the process discussed above, the risers and the dielectric layer can be fabricated entirely by non-selective or self-selective process steps. Thus, no masking or selective photolithographic process steps are required. This greatly simplifies the production process.

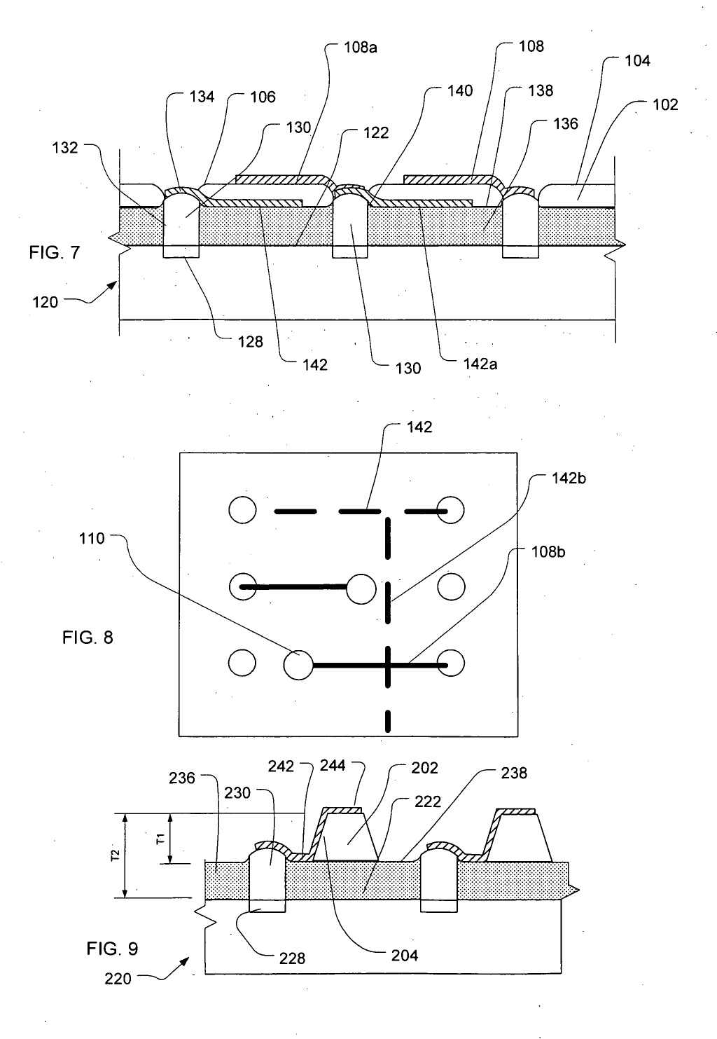

A process according to a further embodiment of the invention uses a body 120 (FIG. 7) which, like the body discussed above, has a front surface 122 and contacts 128 exposed at the front surface. Risers 130 are formed on the contacts in the same manner as discussed above. Here again, following formation of the risers, a first dielectric layer 136 is formed over the front surface 122 of the body around the risers. The flowable liquid composition is applied so as to provide a layer 136 having an average thickness which is just slightly less than the height of risers 130. Thus, the top surface 138 of layer 136 has substantially horizontal principal regions lying below the tips 134 of the risers, and desirably below the junctures between the tip surfaces 134 and the side walls 132 of the risers. The menisci 140 at the junctures between the top surface 138 and the side walls of the risers curve upwardly from the main region 138 to the risers. Here again, the first layer is cured and a set of first traces 142 is formed on the resulting composite surface so that the first traces extend over the top surface 138 of the first dielectric layer 136, and some or all of these first traces extend onto the tips of some or all of the risers 132. The portions of traces 142 overlying the tip surfaces 134 of the risers 130 may effectively merge with the risers and thus slightly increase the height of the risers. Following formation of the first traces, a second dielectric layer 102 is formed over the first dielectric layer 136 and over the first traces 142 by applying a further flowable composition in substantially the same manner as used to form the dielectric layers discussed above. Desirably, layer 102 is thin as, for example, about 10 microns or less, and more desirably about 5 microns or less in nominal thickness. Thus, the second dielectric layer has a top surface 104 with principal regions disposed just slightly above the junctures between the top and side surfaces of the risers. The principal regions of top surface 102 may lie at or slightly above the tops of risers 130. The second dielectric layer 102 desirably does not entirely cover the risers, so that the tip surfaces of the risers (including the overlying first lead portions disposed on the riser tips) remain exposed at the top surface 104 of the second dielectric layer. The flowable composition forms menisci 106, which curve downwardly from the main portion 104 of the second layer top surface to their junctures with the risers, and hence have configurations similar to those discussed above with reference to FIG. 4.

Following curing of the second dielectric layer 102, a set of second traces 108 is formed on the exposed surface, so that some or all of these extend from the tips of the risers. The second traces 108 may be provided with terminals 110, two of which are seen in FIG. 8. The second traces 108 may extend over some of the same risers 130 as the first traces. For example, as seen in FIG. 7, second trace 108a and first trace 142a both overlie and intersect the same riser 130, so that these two traces are connected to one another as well as to the riser. Also, the second traces may extend over and may cross the first traces without being electrically connected thereto. For example, second trace 108b (FIG. 8) extends across first trace 142b, but is not electrically connected thereto, inasmuch as the second dielectric layer 102 intervenes between these crossing traces. The first traces 142 also may extend beneath the terminals 110 associated with the second traces. Thus, the traces can provide a wide variety of routing patterns. The devices and fabrication processes discussed above with reference to FIGS. 7 and 8 provide advantages similar to those discussed above with reference to FIGS. 1-6.

A device according to a further embodiment of the invention (FIG. 9) includes a body 220 having a front surface 222 with contacts 228 as discussed above, and also includes a first dielectric layer 236 and risers 230, substantially as discussed above with reference to FIGS. 1-6. In this embodiment, dielectric projections 202 are provided on the top surface 238 of the dielectric layer. Projections 202 desirably have sloping surfaces 204 disposed at an oblique angle to the horizontal plane. Projections 202 may be formed by depositing a continuous layer of a photoimageable dielectric material over the first dielectric layer and risers, developing the photoimageable material and removing unwanted portions to leave the projections 202. Another selective process which may be employed is molding using a mold having cavities at the locations of the desired projections. Alternatively, the dielectric material forming the projections may be deposited as a continuous layer and then selectively etched using a photoresist or other mask. Traces 242 are formed on the top surface of the first dielectric layer 236 and on the risers 230. The traces also extend up the sloping side surfaces 204 of the projections 202, and some or all of the traces have terminals 244 disposed on the tops of the projections.

In the structure of FIG. 9, the total thickness of the dielectric material underlying the terminals 244 is T₂, the sum of the thickness of the first dielectric layer 236 and the height of the projections. Thus, the structure can provide substantial compliance. However, the process used to form the traces 242 and terminals 244 is only required to span a vertical range T₁ equal to the height of the projections 202 above the top surface of the first dielectric layer. This substantially alleviates the problems encountered in forming vertically-extensive traces.

As discussed above, a relatively thick dielectric layer provides a greater degree of compliance and can be desirable in some instances. However, in some instances, applying a very thick continuous dielectric layer onto the front surface 222 of the body may cause the body to warp. The use of separate projections 202 provides a thickness of dielectric underlying the terminals 244 which is greater than the thickness of the continuous dielectric layer 236, and thus alleviates this effect.

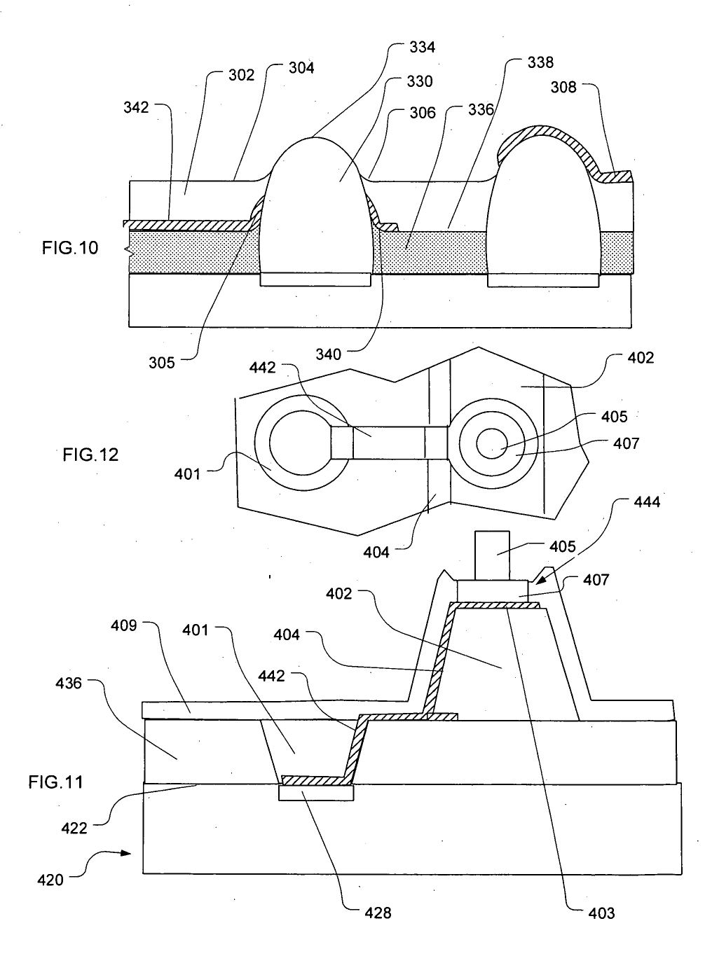

Projections as discussed with reference to FIG. 9 may be provided on the top surfaces of the top-most dielectric layer in any of the structures discussed herein, including the multi-layer structures discussed above with reference to FIGS. 7 and 8, and discussed below with reference to FIG. 10.

A device according to a further embodiment (FIG. 10) includes a first dielectric layer 336 which has a thickness substantially less than the height of risers 330. The device further includes a second dielectric layer 302 having a top surface 304 which is also disposed below the tops of the risers. In this embodiment, the menisci of the first dielectric layer curve upwardly from the top surface 338 of the first dielectric layer to their junctures with the surfaces of risers 330. The menisci 306 of the second dielectric layer also curve upwardly from top surface 304 to their junctures with the riser surfaces. The first traces 342 formed on the top surface of the first dielectric layer contact the risers, but do not extend over the tops of the risers. For example, the first traces may be patterned so as to form metallic collars 305 at their junctures with the risers. Second traces 308 disposed on the top surface of the second dielectric layer may extend over the tops 334 of the risers, or may have a collar-like configuration similar to those of the first traces. The arrangement shown in FIG. 10 can accommodate substantial tolerances in the height of the risers and in the thicknesses of the dielectric layers. Also, three or more dielectric layers may be used, with three or more layers of traces.

A device according to yet a further embodiment of the invention includes a first dielectric layer 436 disposed over the top surface 422 of a semiconductor body 420. In this embodiment, the first dielectric layer has a structure with holes 401 extending through the first dielectric layer to the contacts 428 of the body. Projections 402 having sloping side surfaces 404 are formed on the top surface of layer 436. Thus, the terminals 444 are disposed on the tops of the projections. This embodiment provides benefits similar to those discussed above with reference to FIG. 9, in that the height of the dielectric underlying the terminals 444 can be greater than the thickness of the continuous dielectric layer 436. In this embodiment, however, the traces 442 must extend from the contacts 428 upwardly through the holes 401 and all the way to the tops of the projections 402. Thus, the traces must span the entire range of heights or vertical positions from the contacts 428 through the dielectric layer to tops of the projections. This requirement complicates the task of forming the traces. The traces in this embodiment may be formed by forming a first portion of each trace 442 extending from the contacts upwardly through the hole 401 and onto the top surface of layer 436, and subsequently forming second portions extending upwardly from the first portions to the tops of the projections. For example, in the particular embodiment depicted, the first portions are formed before the projections 402 are applied onto the top surface of layer 436.

In the device of FIGS. 11 and 12, each terminal 444 incorporates a pad 403 formed integrally with the trace. Each terminal further includes a pin 405 extending upwardly above the pad 403. A solder mask layer 409 is disposed over the top surface of the dielectric structure. The pins 405 project above the top of the solder mask layer. A pin base 407 having larger horizontal dimension or diameter than the pin 405 is provided at the bottom of each pin, at its juncture with the pad 403. Merely by way of example, the pins 405 may be generally frustoconical or cylindrical structures having diameters on the order of about 50-300 microns, whereas the bases 407 may be on the order of 100-400 microns in diameter. The pins facilitate engagement of the terminals with test fixtures and bonding of the terminals 444 to a circuit panel. The relatively wide, large-diameter base structures 407 distribute vertical loads applied to pins 405. For example, when a structure such as that depicted in FIGS. 11 and 12 is engaged with a test fixture, the tips of pins 405 may be forced against contact of the test fixture until all of the pins are in engagement with the test fixture. Appreciable vertical loads may be applied to the pins. Bases 407 distribute these loads and thus prevent the pins from breaking through the relatively thin material 403 of the traces and penetrating into the overlying dielectric material.

Terminals such as those shown in FIGS. 11 and 12 may be incorporated in any of the structures discussed herein, and in other structures incorporating pin-type terminals disposed above a dielectric layer.

Numerous variations and combinations of the features discussed herein can be utilized without departing from the present invention as set forth in the claims. For example, self-selective processes other than electroless plating may be used to form the risers. One such self-selective process includes wave-soldering. As described, for example, in U.S. Patent Publication 2004/0035519A1, the disclosure of which is incorporated by reference herein, a wafer may be provided with contacts having underbump metallization suitable for application of a solder. The wafer may be disposed over a bath of a solder with the front surface of the wafer facing downwardly, and a wave may be created within the solder bath so that the wave contacts all portions of the front surface in succession. Masses of solder will cling to the contacts but will not form on the dielectric region surrounding the contacts, which are not wetted by the molten solder. This process may be used to form risers. In a variant, the wave-soldering operation may be repeated so as to gradually build up larger solder masses on the various contacts as risers.

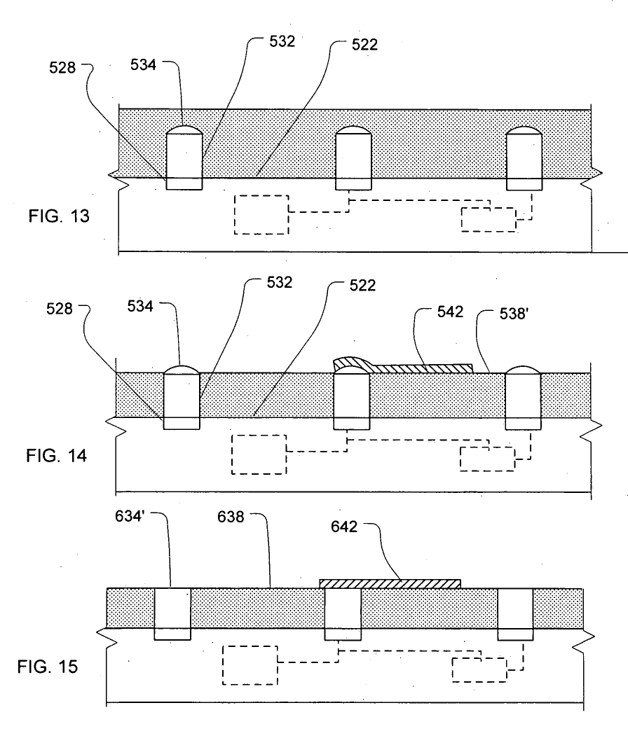

Also, process steps other than those discussed above may be used to apply the various dielectric layers. For example, as shown in FIG. 13, a dielectric layer 536 may be provided on the top surface 522 of a wafer or other body so that the thickness of the dielectric layer is greater than the height of the risers 532. In this condition, the tips 532 of the risers are disposed beneath the top surface 538 of the dielectric layer. Such a dielectric layer may be formed non-selectively as, for example, by applying the dielectric material in a flowable condition using a spin-coating process or by laminating a dielectric to the body after forming the risers, so that the risers penetrate into the dielectric layer. After the dielectric layer is in place, the top surface 538 of the dielectric may be etched using an etchant or solvent which attacks the dielectric but which will not substantially etch the risers as, for example, by plasma etching the dielectric until the tops 534 of the risers are exposed at the etched top surface 538′ of the dielectric layer, as depicted in FIG. 14. The etching process, like the process of applying the dielectric layer itself, may be performed non-selectively. Thus, in this embodiment, the process of applying the dielectric layer includes a non-selective process of forming the dielectric layer and a non-selective process of reducing the thickness of the dielectric layer. Here again, the tips of the risers may project slightly above the top surface 538′ at the completion of this step. Traces 542 are then formed on the top surface 538′ and extend into contact with the risers.

In yet another embodiment, the dielectric layer and the risers may be polished to yield a substantially planar surface (FIG. 15) with the polished tops 634 of the risers co-planar with the top surface 638 of the dielectric layer. For example, the dielectric layer may be formed with a thickness greater than the height of the risers, as discussed above with reference to FIG. 13. After forming the dielectric layer, the assembly is subjected to a non-selective polishing step which is effective to remove material both from the dielectric layer and from the risers, such as a chemical-mechanical polishing process, lapping or other abrasive process. Alternatively, the dielectric layer may be formed with a thickness less than the height of the risers and the assembly may be subjected to a similar non-selective polishing step. In either case, traces 642 desirably are formed on the top surface 638 of the dielectric layer, and here again the traces extend onto the top surfaces of the risers.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of treating a microelectronic device having a front surface and contacts exposed at said front surface comprising the steps of:
(a) forming electrically conductive risers projecting upwardly from said contacts above said front surface; then
(b) applying a first flowable material over said front surface around said risers to form a first dielectric layer with said risers exposed at a top surface of the dielectric layer facing away from the microelectronic device; then
(c) forming first electrically conductive traces extending over said top surface of said dielectric layer, at least some of said traces being connected to at least some of said risers.

2. A method as claimed in claim 1 wherein said step of forming risers is performed using a self-selective deposition technique.

3. A method as claimed in claim 1 wherein said step of forming risers is performed using electroless plating to deposit metal on said contacts.

4. A method as claimed in claim 1 wherein said step of applying a flowable material is performed non-selectively.

5. A method as claimed in claim 1 wherein said step of applying a flowable material is performed by spin-coating.

6. A method as claimed in claim 1 wherein the first flowable material surrounding at least some of said risers lies above or below tips of those risers, and wherein the flowable material wets surfaces of the risers and forms menisci connecting the top surface of the flowable material with the risers.

7. A method as claimed in claim 1 wherein at least some of the risers project above the top surface of the first dielectric layer, the method further comprising the step of applying a second flowable material over the top surface of the first dielectric layer and over the first traces so as to form a second dielectric layer over at least a portion of said first dielectric layer with at least some of said risers exposed at the top surface of the second dielectric layer.

8. A method as claimed in claim 7 further comprising forming second traces on said second dielectric layer.

9. A method as claimed in claim 8 wherein at least some of said second traces are connected to at least some of said risers.

10. A method as claimed in claim 8 wherein at least some of said second traces extend across at least some of said first traces.

11. A method as claimed in claim 1 further comprising forming terminals over said first dielectric layer electrically connected to at least some of said risers by at least some of said traces.

12. A method as claimed in claim 11 further comprising the step of applying an electrically conductive bonding material on terminal regions.

13. A method as claimed in claim 1 further comprising forming dielectric projections overlying said first dielectric layer so that said dielectric projections have sloping side surfaces, said step of forming said first traces being performed so that at least some of said first traces extend from at least some of said risers on the top surface of the first dielectric layer to at least some of said projections and extend up the sloping side walls of such projections.

14. A method as claimed in claim 13 further comprising forming terminals on at least some of said projections, said step of forming said first traces being performed so that at least some of the first traces extend up the sloping side walls to at least some of said terminals.

15. A method as claimed in claim 14 wherein said step of forming said traces is performed using a single photolithographic exposure.

16. A method as claimed in claim 1 wherein said step of applying the dielectric layer includes applying the first flowable material to a thickness greater than the height of the risers to form the first dielectric layer and then removing dielectric material from the layer using a non-selective process.

17. A method as claimed in claim 1 further comprising the step of polishing the first dielectric layer and risers to leave top surfaces of the first dielectric layer and risers substantially coplanar with one another.

18. A method as claimed in claim 1 wherein said microelectronic device is a wafer element including a unitary body having a plurality of regions, the method further comprising severing said body and said first dielectric layer to form a plurality of units, each including one of more of said regions, a portion of the first dielectric layer and some of said first traces.

19. A packaged microelectronic device made by a process as claimed in claim 1.

20. A packaged microelectronic device comprising:
(a) a device body having a front surface and contacts exposed at said front surface;
(b) a first dielectric layer overlying the front surface of the body, the first dielectric layer having a top surface facing away from the body; and
(c) electrically conductive risers projecting upwardly from the contacts, said risers having tips remote from the body exposed at said top surface, said top surface having vertically curved surface regions contiguous with surfaces of said risers.

21. A device as claimed in claim 20 further comprising first traces extending from at least some of said risers across said vertically curved surface regions.

22. A device as claimed in claim 21 wherein said top surface has substantially horizontal main regions remote from said risers, at least some of said first traces extending onto said main regions.

23. A device as claimed in claim 20 wherein at least some of said vertically curved surface regions slope upwardly in directions toward said risers.

24. A device as claimed in claim 20 wherein at least some of said vertically curved surface regions slope upwardly in directions toward said risers.

25. A device as claimed in claim 20 further comprising a second dielectric layer overlying said first dielectric layer, the tips of at least some of said posts being exposed at the top surface of the second dielectric layer.

26. A device as claimed in claim 25 wherein the top surface of said second dielectric layer has vertically curved surface regions contiguous with surfaces of said risers.

27. A device as claimed in claim 26 wherein at least some of the vertically curved surface regions of the top surface of said second dielectric layer slope downwardly in directions toward said risers, and wherein at least some of the vertically curved surface regions of the top surface of the first dielectric layer slope upwardly in directions toward said risers.

28. A device as claimed in claim 25 further comprising first traces extending from at least some of said risers between said first and second dielectric layers and second traces extending from at least some of said risers on the top surface of said second dielectric layer.

29. A device as claimed in claim 28 wherein at least some of said second traces cross at least some of said first traces.

30. A device as claimed in claim 20 further comprising projections extending upwardly from said top surface of said first dielectric layer, said projections having sloping surfaces extending upwardly from said top surface, further comprising traces extending from at least some of said risers over said dielectric layer and upwardly along at least some of said sloping surfaces of said projections.

31. A device as claimed in claim 30 further comprising terminals on at least some of said projections, at least some of said traces extending to at some of said terminals.

32. A device as claimed in claim 20 further comprising terminals on said first dielectric layer, at least some of said traces extending to at least some of said terminals.

33. A device as claimed in claim 32 further comprising masses of electrically conductive bonding material on at least some of said terminals.

34. A method of making a packaged microelectronic device comprising:
(a) forming a dielectric structure on a front surface of the device; and
(b) forming a plurality of continuous traces extending on surfaces of the dielectric structure using a photographic patterning process, said photographic patterning process including a first exposure to form portions of the traces extending in a first range of vertical positions and a second exposure to form portions of the traces extending in a second range of vertical positions.

35. A method as claimed in claim 34 wherein the step of forming a dielectric structure includes a dielectric layer having a top surface, holes extending through the dielectric layer and projections extending upwardly from the top surface of the dielectric layer, said first exposure forming portions of the traces in said holes and said second exposure forming portions of the traces on said projections.

36. A packaged microelectronic device comprising:
(a) a body having a front face and contacts exposed at said front face;
(b) a dielectric structure overlying said front face;
(c) electrically conductive traces extending from said contacts over said dielectric structure, said traces including pads overlying the dielectric structure; and
(d) electrically conductive terminal structures overlying said pads, each said terminal structure including a base and a pin projecting upwardly from said base, said bases having larger diameters than said pins.

37. A device as claimed in claim 36 wherein said dielectric structure includes a dielectric layer and projections extending upwardly from said dielectric layer, and wherein said pads and terminal structures are disposed on said projections.
